(19) United States
(12) Patent Application Publication
(10) Pub. No.: US 2008/0197714 A1
(43) Pub. Date: Aug. 21, 2008

(54) PULSE CIRCUIT

(75) Inventors: Joseph T. Verdeyen, Savoy, IL (US); Brett M. Nee, Metamora, IL (US); David L. Carroll, Urbana, IL (US)

Correspondence Address: ADAM K. SACHAROFF;MUCH SHELIST FREED DENENBERG AMENT&RUBENSTEIN,PC, 191 N. WACKER DRIVE, SUITE 1800, CHICAGO, IL, 60606-1615, US

(73) Assignee: CU AEROSPACE, LLC, Champaign, IL (US)

(21) Appl. No.: 12/030,929

(22) Filed: Feb. 14, 2008

Related U.S. Application Data
(60) Provisional application No. 60/890,208, filed on Feb. 16, 2007.

(51) Int. Cl. H03K 3/00

(52) U.S. Cl. 307/107

(57) ABSTRACT

In an embodiment of the invention there is provided a pulse circuit including two transmission lines or other capacitive energy storage circuits resonantly charged by inductors and diodes that are connected to a DC power source. The pulse circuit includes a pulse transformer that may be connected in series with the transmission lines or artificial lines with a turns ratio chosen to match the load impedance to primary circuit impedance or to generate the optimum pulsed voltage source. Multiple switches can be employed to increase the repetition frequency of the pulses. For transmission lines and L-C artificial lines, the pulse alternates in polarity; for simple capacitive energy storage, the pulses are unipolar.

### CROSS REFERENCE TO RELATED APPLICATIONS

The present invention claims priority to U.S. Provisional Application 60/890,208.

### FIELD OF THE INVENTION

The present invention relates to pulse circuits.

### BACKGROUND OF THE INVENTION

The background of the invention starts with a conventional Blumlein circuit, shown in FIG. 1a. The usual geometry for the Blumlein circuit scheme of pulse generation includes two transmission lines 10 presumably taken as coaxial cables. As shown in prior art FIG. 1a, the inductor 20 and diode 30 are used to resonantly charge the capacitance of each coaxial cable to ˜2*Vₒ, where Vₒ=power supply voltage.

If the load resistance 40, also shown as R_{L}, equals 2 Zₒ (twice the characteristic impedance of the cables), the system is “matched” so that when the switch SW1 is closed, a pulse of amplitude 2Vₒ appears across the resistance, and lasts for 2 I/v seconds where v=the velocity of propagation in the cable.

The operation of the circuit shown in FIG. 1b is identical to that of FIG. 1a provided the pulse transformer 50 transforms the impedance of the load to be 2 Zₒ on the primary side. For coaxial lines, it has the advantage of confining the fields on the inside of the cables, whereas there is a significant coupling to the outside world with load connecting the shields. The fact that 2 inductors and 2 diodes are shown connected to a common power supply ensures that the line recharging current cancels in the primary of the transformers and does not couple to the load resistance.

In the circuit shown in FIG. 1b, the pulse rate is limited by the repetition rate of SW1. The pulse polarity is uni-polar. For a load impedance different from Z₀, a pulsed transformer of turns ratio 1:n can be used.

### SUMMARY OF THE INVENTION

The present invention includes multiple embodiments disclosed and illustrated herein. In one embodiment there is provided a pulse circuit that includes two transmission lines resonantly charged by a pair of inductors and a corresponding pair of diodes which are connected to a power source, shown in FIG. 2. Each inductor and corresponding diode is positioned at one end of each transmission line referred to as the first terminal and a second terminal, respectively. The load impedance device is connected at the other ends of the two lines. A first switch is connected to the transmission line at the first terminal and a second switch is connected to the transmission line at the second terminal. Lastly, a triggering mechanism is configured to close the switches sequentially while avoiding triggering the other switches, such that when the first switch is triggered closed, the second switch remains open, and when the second switch is triggered closed, the first switch remains open. The closure of a switch completely depletes a charge stored on the transmission line and thus a cycle through the closing of the switches creates bipolar pulses that double the output power delivered to the load of the pulse circuit.

In a second embodiment, the previous pulse circuit may further include a secondary pair of charging inductors and diodes connected to the power source, shown in FIG. 3. Each inductor and corresponding diode is positioned along the transmission line at a third and fourth terminal adjacent said first and second terminal, respectively. The second embodiment further includes a third switch connected to the transmission line at the third terminal and a fourth switch connected to the transmission line at the fourth terminal. The triggering mechanism would therefore be further configured to close the switches sequentially while avoiding the triggering of the other switches, such that when the first switch is triggered closed, the second, third and fourth switches remain open, and when the second switch is triggered closed, the first, third and fourth switches remain open, and when the third switch is triggered closed, the first, second and fourth switches remian open, and when the fourth switch is triggered closed, the first, second, and third switches remain open. Thus the closure of any switch completely depletes the energy stored on the transmission line and a cycle through the closing of the switches creates bipolar pulses that quadruple the output power of the pulse circuit as compared to that of the prior art shown in FIG. 1b.

In either embodiment, the load impedance device may be a transformer having a secondary side that is connected to a device that will accept power.

In a third embodiment there is provided a pulse circuit which includes a pair of charging inductors and corresponding primary diodes connected to a power source, shown in FIG. 5a. Each inductor and corresponding diode is separately positioned at a first terminal and a second terminal, respectively. The energy for the pulsed circuit is stored in the capacitance of two artificial transmission lines which in its simplest embodiment consists of a series inductance, connected to terminal 1 and 2 for each line, and a capacitor from the other side of the inductor to ground. A transformer is connected in series between C₁ and C₂ of FIG. 5a and the terminals of the inductors at terminals 3 and 4 and the energy storage capacitors are connected between the two terminals of the pulse transformer and ground. A first switch and a third switch are connected at the first terminal, while a second switch and a fourth switch are both connected at the second terminal. The third embodiment would further include a triggering mechanism configured to close the switches sequentially while avoiding triggering the other switches, such that when the first switch is triggered closed, the second, third and fourth switches remain open, and when the second switch is triggered closed, the first, third and fourth switches remain open, and when the third switch is triggered closed, the first, second and fourth switches remain open, and when the fourth switch is triggered closed, the first, second, and third switches remain open. Therefore, the closure of a switch shorts one of the secondary inductors of the artificial line connected in series to the closed switch and the ringing of the L-C circuit reverses the polarity of the charge stored on the capacitors that are part of one artificial line, thus increasing the voltage across a primary side of the transformer and causing a current to flow from the other capacitor, thereby generating a pulse on the secondary side of the transformer. Thus a cycle through the closing of the switches creates bipolar pulses that quadruple the output of the pulse circuit.

In a fourth embodiment of the present invention, there is provided a pulse circuit that includes a pair of resonant charging inductors and diodes connected to a power source, shown in FIG. 5b. Each inductor and corresponding diode is separately positioned at a first terminal and a second terminal, respectively, with the pulse transformer in the middle. A capacitor is connected to the first terminal and to a transformer; the second capacitor is connected between the second terminal and the pulse transformer. A first and third switch are both connected in parallel at the first terminal, and a second and a fourth switch are connected in parallel at the second terminal. A triggering signal is configured to close each of the switches sequentially while avoiding triggering the others; thus, when the first switch is triggered closed, the second, third and fourth switches remain open, and when the second switch is triggered closed, the first, third and fourth switches remain open, and when the third switch is triggered closed, the first, second and fourth switches remain open, and when the fourth switch is triggered closed, the first, second, and third switches remain open. The closure of a switch places the voltage on the capacitor connected to that switch directly across the primary of the pulse transformer, but with opposite polarity. If, for instance, the resonant charging circuit charged the capacitor to +2V₀, then the pulse voltage applied to the primary of the transformer would be −2V₀. Whereby a cycle through the closing of the switches creates a unipolar pulse that quadruples the power output of the pulse circuit as compared to that which has only one switch.

In a fifth embodiment of the present invention, the fourth embodiment described herein further includes a diode connected in parallel to the primary side of the transformer to provide a low impedance path for the charging current and to avoid coupling of the charging current to the load, shown in FIG. 5c.

### BRIEF DESCRIPTION OF THE DRAWINGS

FIG. 1A is a prior art illustration of a conventional Blumlein circuit diagram;

FIG. 1B is a prior art illustration of a circuit diagram similar to FIG. 1A with a pulse transformer;

FIG. 2 is circuit diagram showing a pulse circuit with switches at each end;

FIG. 3 is a circuit diagram showing a pulse circuit with a pair of switches at each end;

FIG. 4 is a trigger timing diagram for FIGS. 1b, 2, and 3;

FIG. 5A is a circuit diagram showing a pulse circuit with a pair of charging inductors and corresponding primary diodes connected to a power source;

FIG. 5B is a circuit diagram showing a pulse circuit with a pair of resonant charging inductors and diodes connected to a power source; and

FIG. 5C is a circuit diagram showing a pulse circuit with a diode connected in parallel to a primary side of the transformer.

### DETAILED DESCRIPTION OF THE EMBODIMENTS

While the invention is susceptible to embodiments in many different forms, there are shown in the drawings and will be described herein, in detail, the preferred embodiments of the present invention. It should be understood, however, that the present disclosure is to be considered an exemplification of the principles of the invention and is not intended to limit the spirit or scope of the invention by the embodiments illustrated.

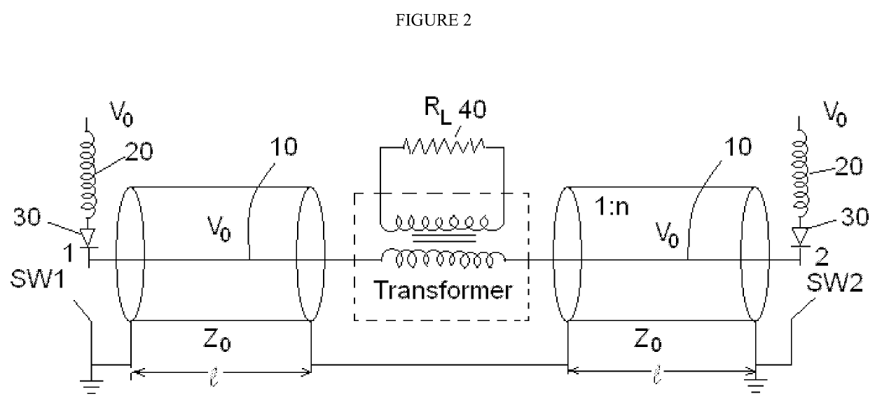

One of the significant modifications of the previous circuits was to incorporate switches at the both ends of the transmission line as shown in FIG. 2.

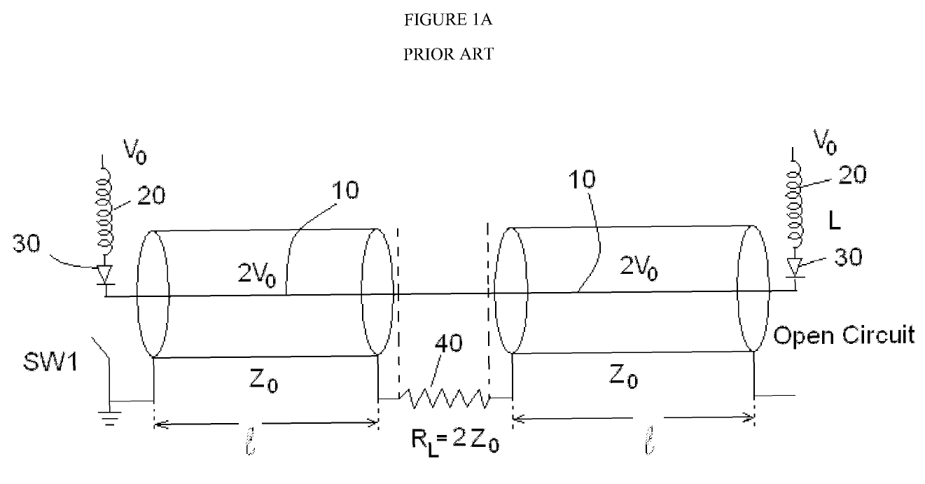

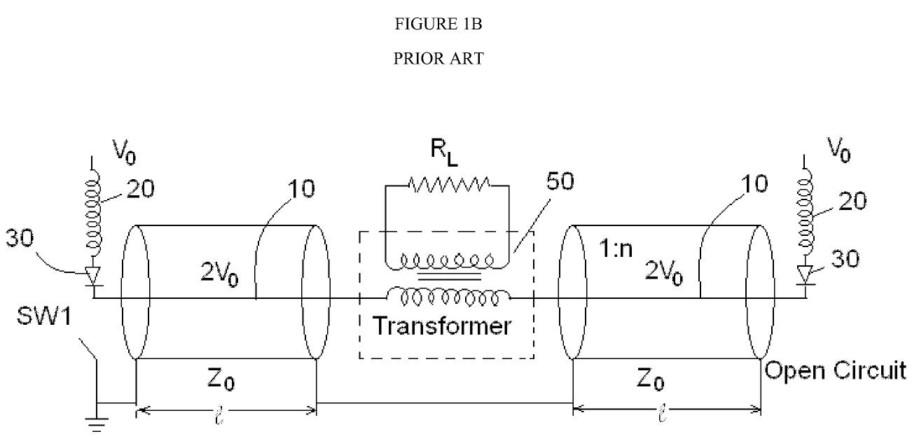

FIG. 2 differs significantly from FIGS. 1a and 1b in that 2 switches are used, one at each end of the transmission line 10. These switches are triggered sequentially, not simultaneously. Therefore, when SW1 is closed, SW2 is open so that the circuit behaves identically to that of FIG. 1b. However, when switch SW2 is closed, SW1 is open and the same sequence is now initiated from the right. Each switch closure completely depletes the charge stored on the line and thus the re-charging of the line from both ends avoids the coupling of the recharge to the load.

The significant difference is that closure of SW2 results in a pulse of opposite polarity to that produced by SW1. Thus this arrangement doubles the output repetition rate, even though each switch is still used at the same rate as in FIG. 1, and as a bonus produces a bipolar pulse.

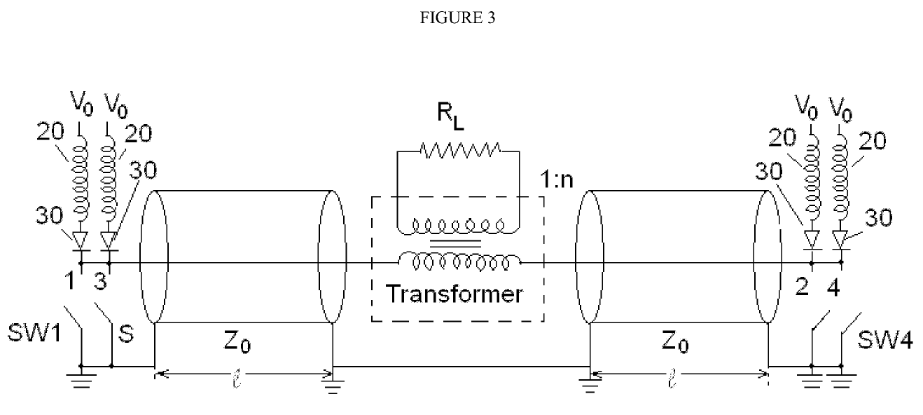

Once it is determined that the sequential triggering of SW1 and SW2 is possible with virtually no interaction between the switches, additional switches were added in parallel at a common point in the manner shown in FIG. 3. Note that the closing of any one switch produces a negative going pulse to the remaining switches, a polarity that naturally minimizes the triggering of those switches.

The switches are triggered sequentially SW1→SW2→SW3→SW4→SW1 . . . generating a bipolar power at 4 times the rate of the conventional circuit in FIG. 1 at the minuscule cost of the increased complexity of the gating circuit. This is easily accomplished with standard logic chips and gate drivers. It has also been determined that adding a parallel resonant charging circuit for each switch speeds up the re-charge time for the energy storage and reduces the power lost in those circuits.

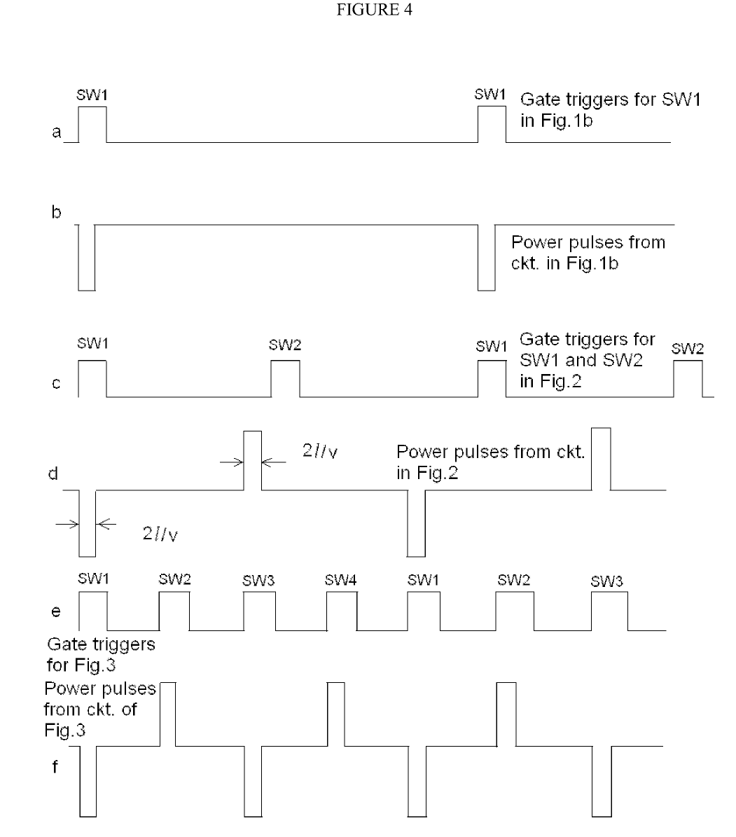

The trigger timing diagrams and the resulting power pulses are shown in FIG. 4. It is presumed that the switches are power semiconductors (for example: MOSFET's or IGBT's) or other devices, in which the switch is closed during the time that the trigger pulse is present and recovers to open circuit shortly after the trigger pulse returns to zero.

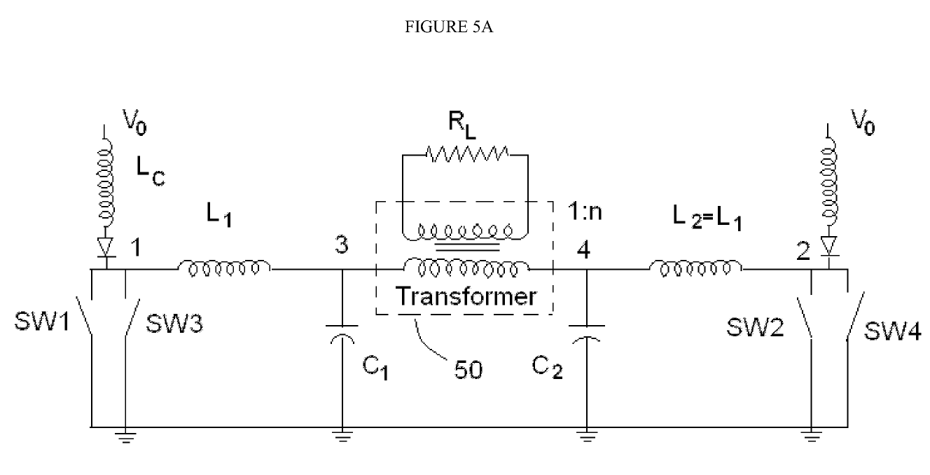

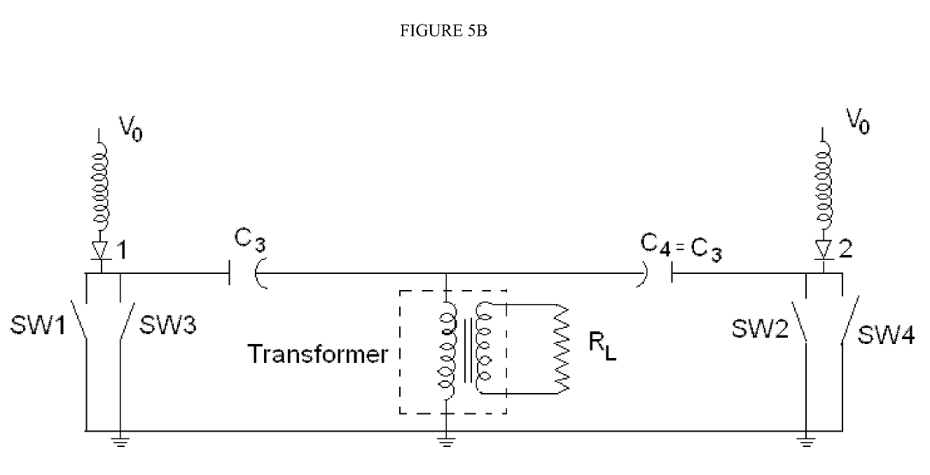

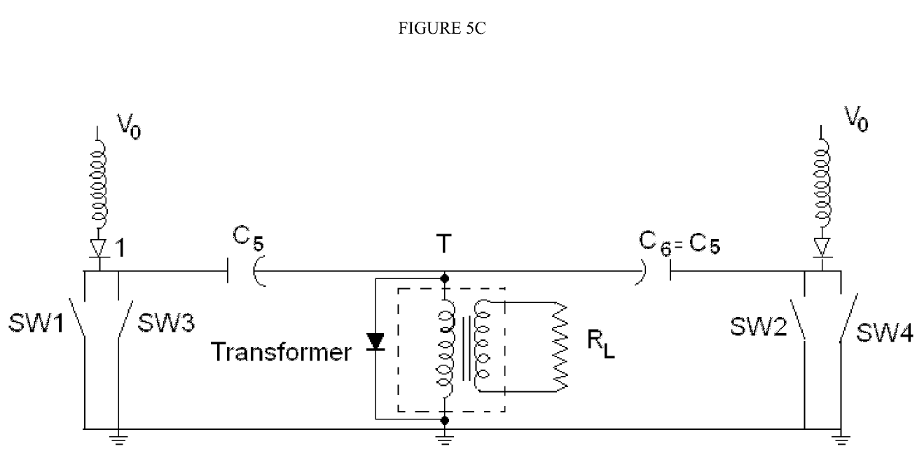

In accordance with the present invention the transmission lines shown in the previous figures can be replaced by an artificial line consisting of discrete circuit components approximating the response of the distributed L and C of a transmission line. One circuit is shown in FIG. 5a and produces a bipolar pulse (FIG. 5a). In FIG. 5a is shown a ringing circuit for the generation of pulses. (L₁=L₂; C₁=C₂).

In the circuit of FIG. 5a, the SW1 (or SW3) shorts L₁ to ground and the resonance between L₁ and C₁ reverses the polarity of the voltage/charge stored on C₁ effectively doubling the voltage across the primary of the transformer. Thus current will flow from C₂ to C₁ reducing both charges to zero, but in the process, generating a pulse in the secondary of the transformer. The effect of shorting SW2 (or SW4) follows the same logic only now starting on the right side of the diagram, FIG. 5a. It will generate a pulse of the opposite polarity to that initiated by SW1.

In FIG. 5b a capacitance discharge circuit is shown. FIG. 5b shows a pulse circuit in which the energy is stored in the two capacitors, C₃ and C₄, which are connected to a pulse transformer and to the switches SW1+SW3 and SW2+SW4, respectively. Triggering any switch places the voltage on the corresponding capacitor across the primary of the pulse transformer and a corresponding output to R_{L}. All switches operate in the same manner and hence this circuit produces a unipolar pulse.

The addition of a diode across the primary of the pulse transformer in FIG. 5B provides a low impedance path for the charging current and thereby would minimize the coupling between the charging cycle and the power pulse. This is shown in FIG. 5c.

The addition of multiple switches in parallel to increase the repetition frequency and thus the pulsed power is limited only by the time to recharge the energy storage devices, the transmission lines or the capacitors. Thus 1, 2, 4, 8, . . . switches could be used.

From the foregoing and as mentioned above, it will be observed that numerous variations and modifications may be effected without departing from the spirit and scope of the novel concept of the invention. It is to be understood that no limitation with respect to the specific methods and apparatus illustrated herein is intended or should be inferred. It is, of course, intended to cover all such modifications.

We claim:

1. A pulse circuit comprising:
a transmission line resonantly charged by a pair of inductors and a corresponding pair of diodes connected to a power source, wherein each inductor and corresponding diode is positioned along the transmission line at a first terminal and a second terminal, respectively;
a load resistance device connected in series between the first and second terminals, the load resistance device having a load resistance matching an impedance created by the pair of inductors;
a first switch connected to the transmission line at the first terminal;
a second switch connected to the transmission line at the second terminal; and
a triggering mechanism configured to close the switches sequentially while avoiding closure of the other switch, such that when the first switch is triggered closed, the second switch remains open, and when the second switch is triggered closed, the first switch remains open, and whereby the closure of either switch completely depletes a charge stored on the transmission line and a cycle through the closing of the switches creates a bipolar pulse that doubles the output power of the pulse circuit.

2. The pulse circuit of claim 1, wherein the load impedance device is a transformer having a secondary side that is connected to a device that will accept power.

3. The pulse circuit of claim 1 further comprising:
an additional pair of inductors and corresponding diodes connected to the power source, each inductor and corresponding diodes being positioned along the transmission line at a third and fourth terminal adjacent said first and second terminal, respectively;
a third switch connected to the transmission line at the third terminal;
a fourth switch connected to the transmission line at the fourth terminal; and
wherein the triggering mechanism is configured to close the switches sequentially while keeping the other switches open, such that when the first switch is triggered closed, the second, third and fourth switches remain open, and when the second switch is triggered closed, the first, third and fourth switches remain open, and when the third switch is triggered closed, the first, second and fourth switches remain open, and when the fourth switch is triggered closed, the first, second, and third switches remain open, whereby the closure of a switch completely depletes a charge stored on the transmission lines and a cycle through the closing of the switches creates a bipolar pulse that quadruples the output of the pulse circuit.

4. The pulse circuit of claim 3, wherein the load impedance device is a transformer having a secondary side that is connected to a device that will accept power.

5. A pulse circuit comprising:
a pair of primary inductors and corresponding primary diodes connected to a power source, each inductor and corresponding diode is separately positioned at a first terminal and a second terminal, respectively;
a transformer connected in series between the third and fourth terminals;
a pair of secondary inductors, each connected in series between the transformer and the first and second terminals, respectively;
a pair of capacitors to ground, connected on either side of the transformer, and wherein the transformer includes a turns ratio such that a load resistance matches the impedance created by the inductor-capacitance combination;
a first switch and a third switch connected at the first terminal;
a second switch and a fourth switch connected at the second terminal; and
a triggering mechanism configured to close the switches sequentially while avoiding triggering the other switches, such that when the first switch is triggered closed, the second, third and fourth switches remain open, and when the second switch is triggered closed, the first, third and fourth switches remain open, and when the third switch is triggered closed, the first, second and fourth switches remain open, and when the fourth switch is triggered closed, the first, second, and third switches remain open, whereby the closure of a switch permits an L-C circuit connected in series to the closed switch to ring reversing the polarity of a charge stored on the capacitor in the L-C circuit, doubling the voltage across a primary side of the transformer and causing a current to flow from the other capacitor on the other side of the transformer, thereby generating a pulse on the secondary side of the transformer and whereby a cycle through the closing of the switches creates a bipolar pulse that quadruples an output of the pulse circuit.

6. A pulse circuit comprising:
a pair of primary inductors and corresponding primary diodes connected to a power source, each inductor and corresponding diode is separately positioned at a first terminal and a second terminal, respectively;
a pair of capacitors connected to the first and second terminals in series;
a transformer connected between the pair of capacitors and ground providing a path for the charging of both capacitors as well as the discharge current of each of the capacitors sequentially;
a first switch and a third switch connected at the first terminal and connected in series with a capacitor and the primary side of the transformer;
a second switch and a fourth switch connected at the second terminal and connected in series with the other capacitor and the primary side of the transformer; and
a triggering mechanism configured to close the switches sequentially while avoiding triggering the other switches, such that when the first switch is triggered closed, the second, third and fourth switches remain open, and when the second switch is triggered closed, the first, third and fourth switches remain open, and when the third switch is triggered closed, the first, second and fourth switches remain open, and when the fourth switch is triggered closed, the first, second, and third switches remain open, whereby the closure of any switch connects both terminals of the corresponding capacitor directly across the primary of the transformer and thus current will flow in the load connected to a secondary side of the transformer, and wherein the polarity of a voltage of the pulse applied to the primary side of the transformer is always negative and thus does not trigger the switches that are open and a cycle through the closing of the switches creates results in a uni-polar pulse at four times the rate of a single switch circuit.

7. The pulse circuit of claim 6 further comprising:
a diode connected in parallel to the primary side of the transformer to avoid the leak inductance of the primary of the transformer.
